(19) United States
(12) Patent Application Publication
(10) Pub. No.: US 2026/0142630 A1
(43) Pub. Date: May 21, 2026

(54) AMPLIFIER GAIN SHAPING CONTROL

(71) Applicant: MACOM Technology Solutions Holdings, Inc., Lowell, MA (US)

(72) Inventors: Duy P. Nguyen, San Jose, CA (US); Trong Phan, Garden Grove, CA (US); Nguyen L.K. Nguyen, Bedford, MA (US); Wayne Kennan, Palo Alto, CA (US); Stefano D'Agostino, Los Altos, CA (US); William M. Allen, Gansevoort, NY (US)

(21) Appl. No.: 18/950,702

(22) Filed: Nov. 18, 2024

(51) Int. Cl. H03F 3/45; H03G 1/00

(52) U.S. Cl. CPC H03F 3/4508; H03G 1/0029; H03F 2200/267; H03F 2200/498

(57) ABSTRACT

Amplifiers with new circuit topologies for gain shaping and gain control are described herein. An example amplifier circuit with gain control includes a differential transistor pair, a main transistor pair coupled to the differential transistor pair, an auxiliary transistor pair coupled to the differential transistor pair, and a resistive impedance coupled between base terminals of the auxiliary transistor pair. The resistive impedance can include a pair of matched resistors coupled between base terminals of the auxiliary transistor pair. The amplifier can also include a capacitor coupled from a virtual ground node between the pair of matched resistors to ground. The amplifier circuits described herein can present a preferred gain response as compared to other amplifiers, at both midband and peaking frequencies. The amplifier circuits also offer additional options for control of gain at midband frequencies, among other benefits.

### BACKGROUND

A range of different amplifiers are known and relied upon for data communications. Differential amplifiers, as an example, are commonly used for high-speed data communications. Differential amplifiers are designed to amplify the difference between two input signals and to reject noise or interference that is present on both (i.e., common to) the input signals. Differential amplifiers are often used as the first amplifier stage in operational amplifiers, and multiple stages of differential amplifiers can be cascaded depending on design needs and the amplification application. Each amplifier stage can have a different amplifier configuration.

### SUMMARY

Certain aspects of the concepts and embodiments described herein are summarized below. The aspects are representative and not exhaustively listed. In alternate embodiments, certain features and elements can be added, omitted, and interchanged with each other. Additionally, variations, extensions, and modifications to the example embodiments can be achieved by those skilled in the art without departing from the concepts, so as to encompass equivalent and related structures.

Amplifiers with new circuit topologies for gain shaping and gain control are described herein. An example amplifier circuit with gain control includes a differential transistor pair, a main transistor pair coupled to the differential transistor pair, an auxiliary transistor pair coupled to the differential transistor pair, and a resistive impedance coupled between base terminals of the auxiliary transistor pair. The resistive impedance can include a pair of matched resistors coupled between base terminals of the auxiliary transistor pair. The amplifier can also include a capacitor coupled from a virtual ground node between the pair of matched resistors to ground. The amplifier circuits described herein can present a preferred gain response as compared to other amplifiers, at both midband and peaking frequencies. The amplifier circuits also offer additional options for control of gain at midband frequencies, among other benefits.

In other aspects, the differential transistor pair can include a first differential transistor and a second differential transistor, and the main transistor pair can include a first main transistor and a second main transistor. An emitter terminal of the first main transistor can be coupled to a collector terminal of the first differential transistor. An emitter terminal of the second main transistor can be coupled to a collector terminal of the second differential transistor. Further, the auxiliary transistor pair can include a base-coupled auxiliary transistor pair. The resistive impedance can be coupled between base terminals of the auxiliary transistor pair, and emitter terminals of the auxiliary transistor pair can be coupled to collector terminals of the differential transistor pair. In some cases, the emitter terminals of the main transistor pair can also be coupled to the collector terminals of the differential transistor pair.

In other aspects, a differential input to the amplifier circuit can be applied across base terminals of the differential transistor pair, and a differential output from the amplifier circuit is taken across collector terminals of the main transistor pair. A gain control signal can be applied at base terminals of the main transistor pair and at the base terminals of the auxiliary transistor pair.

Another example amplifier circuit with gain control includes a main transistor pair, an auxiliary transistor pair, and a resistive impedance coupled between base terminals of the auxiliary transistor pair. Still another example amplifier circuit includes a main transistor pair, an auxiliary transistor pair, and an impedance including resistive and capacitive elements coupled between base terminals of the auxiliary transistor pair.

### BRIEF DESCRIPTION OF THE DRAWINGS

Aspects of the present disclosure can be better understood with reference to the following drawings. It is noted that the elements in the drawings are not necessarily drawn to scale, with emphasis instead being placed upon illustrating the principles of the examples. In the drawings, like reference numerals designate like or corresponding, but not necessarily the same, elements throughout the several views.

FIG. 1 illustrates an example multi-stage amplifier according to various examples described herein.

FIG. 2 illustrates an example amplifier circuit with variable gain according to various examples described herein.

FIG. 3 illustrates an example plot of normalized gain for different gain settings of the amplifier circuit shown in FIG. 2 according to various examples described herein.

FIG. 4 illustrates another example amplifier circuit with variable gain and gain shaping control according to various examples described herein.

FIG. 5 illustrates an example plot of normalized gain for different gain settings of the amplifier circuit shown in FIG. 4 according to various examples described herein.

### DETAILED DESCRIPTION

Receivers, transmitters, and transceivers for emerging data communication applications rely upon amplifier circuits to transfer data signals at higher speeds. The amplifier circuits are often designed for broadband operation and, in some cases, variable gain control. Differential amplifiers are commonly used for high-speed data communications. Multiple stages of differential amplifiers can be cascaded or connected in series depending on the design needs of a given amplifier application. It can be important to tailor and optimize the operating criteria and performance of each amplifier stage in a multi-stage amplifier.

Amplifiers with new circuit topologies for gain shaping and gain control are described herein. An example amplifier circuit with gain control includes a differential transistor pair, a main transistor pair coupled to the differential transistor pair, an auxiliary transistor pair coupled to the differential transistor pair, and a resistive impedance coupled between base terminals of the auxiliary transistor pair. The resistive impedance can include a pair of matched resistors coupled between base terminals of the auxiliary transistor pair. The amplifier can also include a capacitor coupled from a virtual ground node between the pair of matched resistors to ground. The amplifier circuits described herein can present a preferred gain response as compared to other amplifiers, at both midband and peaking frequencies. The amplifier circuits also offer additional options for control of gain at midband frequencies, among other benefits.

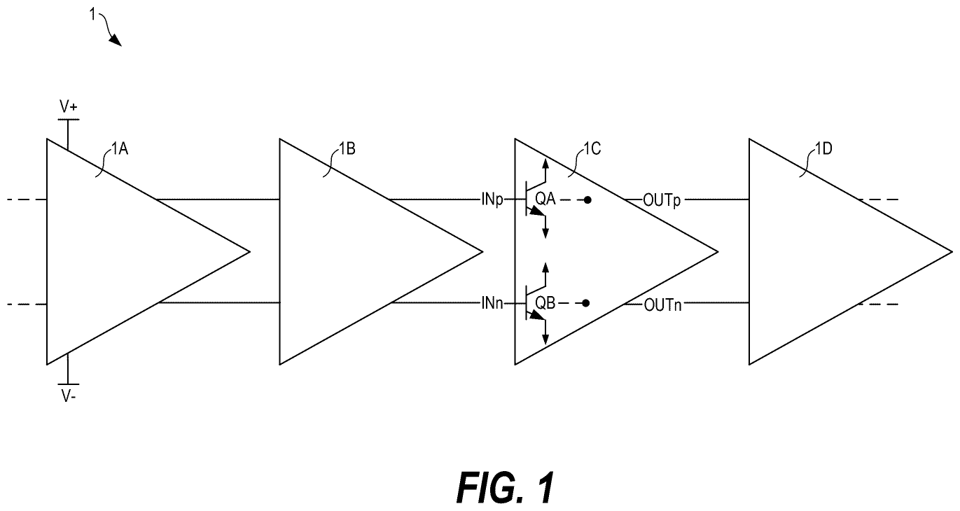

FIG. 1 illustrates an example multi-stage amplifier 1 according to various examples described herein. The multi-stage amplifier 1 can be embodied in various ways, such as using discrete components, as an integrated circuit device formed on a substrate, or as a combination of discrete components and integrated devices. The multi-stage amplifier 1 is depicted as a representative example. The multi-stage amplifier 1 is not exhaustively illustrated in FIG. 1, and the multi-stage amplifier 1 can include additional components that are not shown in some cases. The multi-stage amplifier 1 can also omit certain amplifier stages or components in other cases.

The multi-stage amplifier 1 includes a number of cascaded amplifier circuits or stages, including amplifier stages 1A-1D, among possibly others. In the cascaded configuration shown, the outputs of the amplifier stage 1A are provided as inputs to the amplifier stage 1B. The outputs of the amplifier stage 1B are provided as inputs to the amplifier stage 1C, and so on. Multi-stage amplifiers can be relied upon for increased overall gain, to tailor input or output impedances, and to achieve other objectives for certain data communications applications. Each of the amplifier stages 1A-1D is supplied with power by an upper rail voltage or potential V+ and a lower rail voltage or potential V−.

Each of the amplifier stages 1A-1D can include one or more transistor amplifiers, biasing circuitry, coupling circuitry, and related circuit components. Additionally, the transistor or transistors in each of the amplifier stages 1A-1D can be arranged or configured in different ways (e.g., distributed amplifiers, differential pair amplifiers, Darlington pair amplifiers, common collector or drain amplifiers, common emitter or source amplifiers, common base or gate amplifiers, etc.) depending on the design, objectives, and application for the multi-stage amplifier 1. The amplifier stage 1C is shown to include two transistors QA and QB, as an example, for handling a differential signal. Each of the amplifier stages 1A-1D can be designed, tailored, and optimized independently.

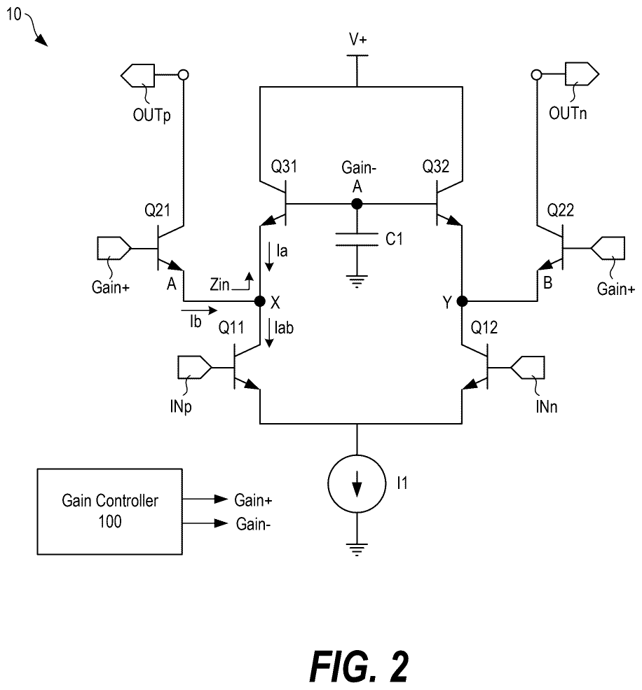

FIG. 2 illustrates an example amplifier circuit 10 with variable gain according to various examples described herein. The amplifier circuit 10 can be embodied in various ways, such as using discrete components, as an integrated circuit device formed on a substrate, or as a combination of discrete components and integrated devices. The amplifier circuit 10 is provided as a representative example of an amplifier stage with variable gain control. The amplifier circuit 10 is not exhaustively illustrated in FIG. 2, and the amplifier circuit 10 can include additional components that are not shown. The amplifier circuit 10 can also omit certain components in some cases.

The amplifier circuit 10 shown in FIG. 2 is an example of a variable gain amplifier. The amplifier circuit 10 can be used as a variable gain amplifier or driver stage for radio frequency (RF) communications, wired communications, optical communications, or for other purposes, without limitation. The gain of the amplifier circuit 10 can be varied based on a control input, as described below. The amplifier circuit 10 can be implemented as one of the amplifier stages 1A-1D of the multi-stage amplifier 1 shown in FIG. 1. As one example, an input of the amplifier circuit 10 in the multi-stage amplifier 1 can be coupled to an output of a distributed amplifier stage in the multi-stage amplifier 1. The amplifier circuit 10 can also be connected in other ways and to other amplifier stages in a multi-stage amplifier. The amplifier circuit 10 can also be implemented as a stand-alone amplifier circuit, rather than as part of a multi-stage amplifier.

The amplifier circuit 10 includes a differential transistor pair of transistors Q11 and Q12 (also “differential transistors Q11 and Q12”), a main transistor pair of transistors Q21 and Q22 (also “main transistors Q21 and Q22”), an auxiliary transistor pair of transistors Q31 and Q32 (also “auxiliary transistors Q31 and Q32”), a current source I1, and a capacitor C1 electrically coupled in the arrangement shown, among possibly other components. FIG. 2 also illustrates a gain controller 100 for the amplifier circuit 10, which is described in further detail below.

The amplifier circuit 10 is not exhaustively illustrated in FIG. 2, and the amplifier circuit 10 can include additional components that are not shown for biasing, coupling, and other purposes in some cases. As one example, one or more resistors or other circuit components can be coupled between the emitter terminals of the differential transistors Q11 and Q12 and the current source I1. As another example, one or more resistors can be coupled between the collector terminals of the main transistors Q21 and Q22 and the upper rail voltage V+. Interstage coupling, blocking, and other capacitors can also be relied upon in some cases as would be understood in the field.

The transistors Q11, Q12, Q21, Q22, Q31, and Q32 are depicted as bipolar junction transistors in FIG. 2. The transistors can be embodied as field effect transistors (FETs) or other types of transistors in other cases, however, and the concepts described herein are not limited to use with amplifiers or transistors of any particular type or technology. Thus, references to the “base” or “base terminal” of a transistor include a reference to the “gate” or “gate terminal” of a FET transistor. Similarly, references to the “emitter” or “emitter terminal” of a transistor include a reference to the “source” or “source terminal” of a FET transistor, and references to the “collector” or “collector terminal” of a transistor include a reference to the “drain” or “drain terminal” of a FET transistor. Other types and configurations of amplifiers and amplifier circuits can also incorporate the amplifier gain shaping and control concepts described herein.

The emitter terminals of the differential transistors Q11 and Q12 are coupled together and to the current source I1. The current source I1 is coupled between the emitter terminals of the differential transistors Q11 and Q12 and ground or, in some cases, a lower rail voltage or potential V−. The emitter terminals of the auxiliary transistors Q31 and Q32 are coupled to the collectors of the differential transistors Q11 and Q12, respectively. The base terminals of the auxiliary transistors Q31 and Q32 are coupled to each other, and the auxiliary transistor pair of transistors Q31 and Q32 can be referred to as a base-connected auxiliary transistor pair. The node “A” between the base terminals of the auxiliary transistors Q31 and Q32 is an AC or virtual ground in the amplifier circuit 10, and the capacitor C1 is coupled between the node “A” and ground or, in some cases, a lower rail voltage or potential V−. The collector terminals of the auxiliary transistors Q31 and Q32 are coupled to the upper rail voltage or potential V+.

The emitter terminals of the main transistors Q21 and Q22 are coupled to the collector terminals of the differential transistors Q11 and Q12, respectively. The emitter terminals of the main transistors Q21 and Q22 are also coupled to the emitter terminals of the auxiliary transistors Q31 and Q32, respectively. Thus, the emitter terminal of the main transistor Q21, the collector terminal of the differential transistor Q11, and the emitter terminal of the auxiliary transistor Q31 are coupled together at the node “X” shown in FIG. 2. Additionally, the emitter terminal of the main transistor Q22, the collector terminal of the differential transistor Q12, and the emitter terminal of the auxiliary transistor Q32 are coupled together at the node “Y” shown in FIG. 2.

A differential input INp and INn can be provided to the base terminals of the differential transistors Q11 and Q12 of the amplifier circuit 10. A differential output OUTp and OUTn from the amplifier circuit 10 can be taken from the collector terminals of the main transistors Q21 and Q22. Although not shown in FIG. 2, the collector terminals of the main transistors Q21 and Q22 can be coupled to the upper rail voltage or potential V+.

The gain controller 100 is configured to generate a gain control signal or gain bias potential across the Gain+ and Gain− inputs to the amplifier circuit 10. The gain controller 100 can be embodied as any suitable type of control circuit, including an analog, digital, or combination analog/digital control circuit. In some cases, the gain controller 100 can be implemented as a separate, and external, control device in a separate device package from the amplifier 10. The gain controller 100 can also be implemented, in part or whole, on the same semiconductor substrate or die as the amplifier circuit 10. The gain of the amplifier circuit 10 can be adjusted based on a potential difference present across the Gain+ and Gain− inputs to the amplifier circuit 10, as generated by the gain controller 100. As shown in FIG. 2, Gain+is applied at the base terminals of the main transistors Q21 and Q22, and Gain− is applied at the base terminals of the auxiliary transistors Q31 and Q32.

The current source I1 is representative in FIG. 2 and can be implemented as any suitable type of current source or related biasing circuitry for the differential transistors Q11 and Q12 and the amplifier circuit 10. Examples of the current source I1 include transistor-based current mirrors, current regulators, resistors, and combinations thereof, and the current source I1 is not limited to any particular type of current source. The current source I1 can also be implemented as a variable current source in some cases.

The upper rail voltage V+ can be any suitable voltage. In some cases, the circuit ground can be embodied as a lower rail voltage V−, which can also be any suitable voltage or potential that is less than the upper rail voltage V+. The voltages V+ and V− can be selected, respectively, based on the target biasing voltage or voltage range for the amplifier circuit 10. The difference in potential between the upper rail voltage V+ and ground or between the upper rail voltage V+−and the lower rail voltage V− can be any suitable potential difference based on the target biasing voltage or voltage range for the amplifier circuit 10.

The amplifier circuit 10 can be biased for operation at a nominal gain and also a variable gain based on the potential applied across the Gain+ and Gain− inputs. In that sense, the amplifier circuit 10 can be designed to have the appropriate potentials at the terminals of the transistors Q11, Q12, Q21, Q22, Q31, and Q32 for operation at nominal and variable gain. Beyond biasing for nominal gain, the gain of the amplifier circuit 10 can be adjusted based on a potential difference applied across the Gain+ and Gain− inputs to the amplifier circuit 10. Gain+ is applied at the base terminals of the main transistors Q21 and Q22, and Gain− is applied at the base terminals of the auxiliary transistors Q31 and Q32.

The gain controller 100 is configured to generate a first potential difference between Gain+ and Gain− for a maximum gain setting of the amplifier circuit 10. The first potential difference between Gain+ and Gain− for maximum gain can be selected depending on the nominal biasing for the amplifier circuit 10 and other factors, as would be understood in the field. The potential difference between Gain+ and Gain− for maximum gain can be selected such that the auxiliary transistors Q31 and Q32 are turned off. In that case, the impedance Zin looking into the emitter of the auxiliary transistor Q31 from the node “X” is very high or infinite. Similarly, the impedance looking into the emitter of the auxiliary transistor Q32 from the node “Y” is very high or infinite when the amplifier circuit 10 is operating at maximum gain. In this maximum gain setting, the current Ia from the auxiliary transistor Q31 can be zero or near zero, and the current Iab flowing into the collector terminal of the differential transistor Q11 can be the same or substantially the same as the current Ib from the main transistor Q21.

The gain controller 100 is also configured to generate a second potential difference between Gain+ and Gain− for a minimum gain setting of the amplifier circuit 10. The second potential difference between Gain+ and Gain− for minimum gain can also be selected depending on the nominal biasing for the amplifier circuit 10 and other factors, as would be understood in the field. In any case, the second potential difference between Gain+ and Gain− for the minimum gain setting is lower than the maximum potential difference between Gain+ and Gain− for the maximum gain setting.

The potential difference between Gain+ and Gain− for minimum gain can be selected such that the auxiliary transistors Q31 and Q32 are turned on. In that case, the impedance Zin looking into the emitter of the auxiliary transistor Q31 from the node “X” decreases, and it is not as high as when the auxiliary transistors Q31 and Q32 are turned off. Similarly, the impedance looking into the emitter of the auxiliary transistor Q32 from the node “Y” decreases, and it is not as high as when the amplifier circuit 10 is operating at maximum gain. In this minimum gain setting, the current Ia from the auxiliary transistor Q31 is greater than zero and forms part of the current Iab flowing into the collector terminal of the differential transistor Q11, along with the current Ib from the main transistor Q21.

At maximum gain for the amplifier circuit 10, the auxiliary transistors Q31 and Q32 are turned off and present a very high impedance and no loading effect on the nodes “X” and “Y”. At the minimum gain for the amplifier circuit 10, the auxiliary transistors Q31 and Q32 are on and present an impedance and loading effect on the nodes “X” and “Y”. It should be appreciated that the amplifier circuit 10 can also operate at a range of intermediate gain settings between maximum and minimum gain, and the gain controller 100 is configured to generate other potential differences (e.g., besides the first and second for maximum and minimum, respectively) between Gain+ and Gain− for other gain settings of the amplifier circuit 10. In any case, the loading effect presented by the auxiliary transistors Q31 and Q32 at lower gain settings leads to lower gain for the amplifier circuit 10, but more particularly lower gain at higher frequencies.

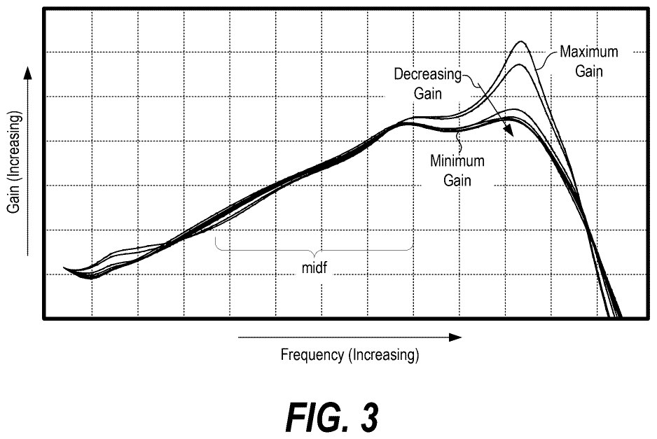

FIG. 3 illustrates an example plot of normalized gain for different gain settings of the amplifier circuit 10 shown in FIG. 2. Gain curves for maximum, minimum, and other gain settings are shown, over operating frequency for the amplifier circuit 10, and the maximum and minimum gain curves are separately referenced in FIG. 3. As shown, the loading effect presented by the auxiliary transistors Q31 and Q32 results in lower gain for lower gain settings of the amplifier circuit 10, particularly at higher frequencies. The difference in gain among the gain settings of the amplifier circuit 10 is less pronounced at the lower, “midf” frequencies, regardless of the gain setting. For certain data communication and other applications, it can be preferrable to have less variation among the gain settings of an amplifier at higher, peaking frequencies, and more variation among the gain settings of the amplifier at lower frequencies.

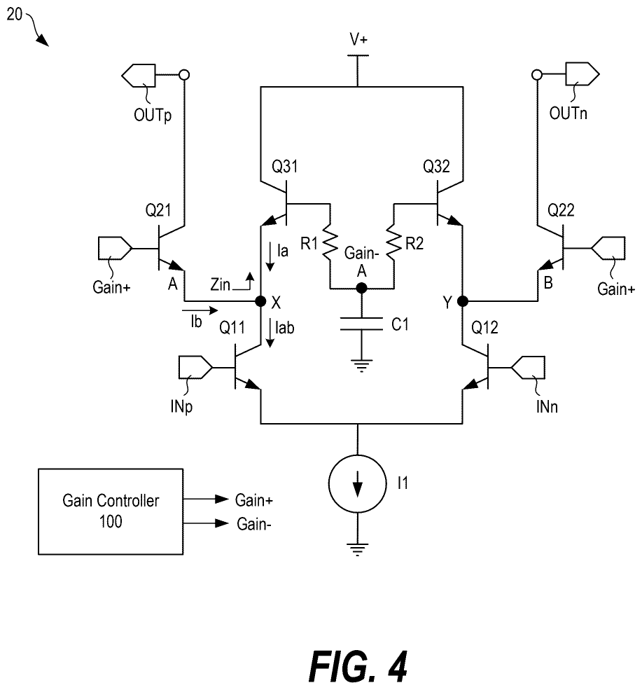

FIG. 4 illustrates another example amplifier circuit 20 with variable gain and gain shaping control according to various examples described herein. The amplifier circuit 20 can be embodied in various ways, such as using discrete components, as an integrated circuit device formed on a substrate, or as a combination of discrete components and integrated devices. The amplifier circuit 20 is provided as a representative example of an amplifier stage with variable gain control. The amplifier circuit 20 is not exhaustively illustrated in FIG. 4, and the amplifier circuit 20 can include additional components that are not shown. The amplifier circuit 20 can also omit certain components in some cases.

The amplifier circuit 20 shown in FIG. 4 is an example of a variable gain amplifier. The amplifier circuit 20 can be used as a variable gain amplifier or driver stage for RF communications, wired communications, optical communications, or for other purposes, without limitation. The gain of the amplifier circuit 20 can be varied based on a control input, as described below. The amplifier circuit 20 can be implemented as one of the amplifier stages 1A-1D of the multi-stage amplifier 1 shown in FIG. 1. As one example, an input of the amplifier circuit 10 in the multi-stage amplifier 1 can be coupled to an output of a distributed amplifier stage in the multi-stage amplifier 1. The amplifier circuit 20 can also be connected in other ways and to other amplifier stages in a multi-stage amplifier. The amplifier circuit 20 can also be implemented as a stand-alone amplifier circuit, rather than as part of a multi-stage amplifier.

The amplifier circuit 20 includes the differential transistors Q11 and Q12, the main transistors Q21 and Q22, the auxiliary transistors Q31 and Q32, the current source I1, resistors R1 and R2, and the capacitor C1 electrically coupled in the arrangement shown, among possibly other components. FIG. 3 also illustrates the gain controller 100 for the amplifier circuit 20, which is described in further detail below. The base terminals of the auxiliary transistors Q31 and Q32 are coupled together, and the auxiliary transistors Q31 and Q32 can be referred to as a base-coupled transistor pair. In the amplifier circuit 20, an impedance including a combination of resistive and capacitive elements is electrically coupled between the base terminals of the auxiliary transistors Q31 and Q32.

The amplifier circuit 20 is not exhaustively illustrated in FIG. 4, and the amplifier circuit 20 can include additional components that are not shown for biasing, coupling, and other purposes in some cases. As one example, one or more resistors or other circuit components can be coupled between the emitter terminals of the differential transistors Q11 and Q12 and the current source I1. As another example, one or more resistors can be coupled between the collector terminals of the main transistors Q21 and Q22 and the upper rail voltage V+. Interstage coupling, blocking, and other capacitors can also be relied upon in some cases as would be understood in the field.

The transistors Q11, Q12, Q21, Q22, Q31, and Q32 are depicted as bipolar junction transistors in FIG. 4. The transistors can be embodied as FETs or other types of transistors in other cases, however, and the concepts described herein are not limited to use with amplifiers or transistors of any particular type or technology. Other types and configurations of amplifiers and amplifier circuits can also incorporate the amplifier gain shaping and control concepts described herein.

In the amplifier circuit shown in FIG. 4, the base terminals of the auxiliary transistors Q31 and Q32 are coupled to each other, but the resistors R1 and R2 are inserted between the base terminals of the auxiliary transistors Q31 and Q32. The node “A” between the resistors R1 and R2 is an AC or virtual ground in the amplifier circuit 20, and the capacitor C1 is coupled between the node “A” and ground or, in some cases, a lower rail voltage or potential V−.

A differential input INp and INn can be provided to the base terminals of the differential transistors Q11 and Q12 of the amplifier circuit 20. A differential output OUTp and OUTn from the amplifier circuit 20 can be taken from the collector terminals of the main transistors Q21 and Q22. Although not shown in FIG. 4, the collector terminals of the main transistors Q21 and Q22 can be coupled to the upper rail voltage or potential V+.

The gain controller 100 is configured to generate a gain bias potential across the Gain+ and Gain− inputs to the amplifier circuit 20. The gain of the amplifier circuit 20 can be adjusted based on the potential difference present across the Gain+ and Gain− inputs to the amplifier circuit 20, as generated by the gain controller 100. As shown in FIG. 4, Gain+ is applied at the base terminals of the main transistors Q21 and Q22, and Gain− is applied at the node “A” between the resistors R1 and R2.

The amplifier circuit 20 can be biased for operation at a nominal gain and also a variable gain based on the potential applied across the Gain+ and Gain− inputs. In that sense, the amplifier circuit 20 can be designed to have the appropriate potentials at the terminals of the transistors Q11, Q12, Q21, Q22, Q31, and Q32 for operation at nominal and variable gain. Beyond biasing for nominal gain, the gain of the amplifier circuit 20 can be adjusted based on a potential difference applied across the Gain+ and Gain− inputs to the amplifier circuit 20. Gain+ is applied at the base terminals of the main transistors Q21 and Q22, and Gain− is applied at the base terminals of the auxiliary transistors Q31 and Q32.

The gain controller 100 is configured to generate a first potential difference between Gain+ and Gain− for a maximum gain setting of the amplifier circuit 20. The first potential difference between Gain+ and Gain− for maximum gain can be selected depending on the nominal biasing for the amplifier circuit 20 and other factors, as would be understood in the field. The potential difference between Gain+ and Gain− for maximum gain can be selected such that the auxiliary transistors Q31 and Q32 are turned off. In that case, the impedance Zin looking into the emitter of the auxiliary transistor Q31 from the node “X” is very high or infinite. Similarly, the impedance looking into the emitter of the auxiliary transistor Q32 from the node “Y” is very high or infinite when the amplifier circuit 20 is operating at maximum gain. In this maximum gain setting, the current Ia from the auxiliary transistor Q31 can be zero or near zero, and the current Iab flowing into the collector terminal of the differential transistor Q11 can be the same or substantially the same as the current Ib from the main transistor Q21.

The gain controller 100 is also configured to generate a second potential difference between Gain+ and Gain− for a minimum gain setting of the amplifier circuit 20. The second potential difference between Gain+ and Gain− for minimum gain can also be selected depending on the nominal biasing for the amplifier circuit 20 and other factors, as would be understood in the field. In any case, the second potential difference between Gain+ and Gain− for the minimum gain setting is lower than the maximum potential difference between Gain+ and Gain− for the maximum gain setting.

The potential difference between Gain+ and Gain− for minimum gain can be selected such that the auxiliary transistors Q31 and Q32 are turned on. In that case, the impedance Zin looking into the emitter of the auxiliary transistor Q31 from the node “X” decreases, and it is not as high as when the auxiliary transistors Q31 and Q32 are turned off. Similarly, the impedance looking into the emitter of the auxiliary transistor Q32 from the node “Y” decreases, and it is not as high as when the amplifier circuit 20 is operating at maximum gain. In this minimum gain setting, the current Ia from the auxiliary transistor Q31 is greater than zero and forms part of the current Iab flowing into the collector terminal of the differential transistor Q11, along with the current Ib from the main transistor Q21.

At maximum gain for the amplifier circuit 10, the auxiliary transistors Q31 and Q32 are turned off and present a very high impedance and no loading effect on the nodes “X” and “Y”. At the minimum gain for the amplifier circuit 10 (and at all gain settings less than the maximum gain), the auxiliary transistors Q31 and Q32 are on and present an impedance and loading effect on the nodes “X” and “Y”. However, the loading effect presented on the nodes “X” and “Y” by the auxiliary transistors Q31 and Q32 is reduced in the amplifier 20 shown in FIG. 4 as compared to the amplifier 10 shown in FIG. 2, when operating at less than maximum gain. The use of the resistors R1 and R2 in the amplifier 20 results in a relatively larger Zin of the auxiliary transistor Q31, and of the auxiliary transistor Q32, when the amplifier circuit 20 shown in FIG. 4 is operating at lower gain settings as compared to the amplifier circuit 10 shown in FIG. 2.

The resistors R1 and R2 can be matched resistors of equal resistance. The resistors R1 and R2 can range in value from about 50 Ω to 400 Ω each, and other values can be used in other cases. Example values for the resistors R1 and R2 include 50 Ω, 100 Ω, 150 Ω, and 200 Ω each, and other values can be relied upon. The use of the resistors R1 and R2 leads to relatively larger input impedances at the emitter terminals of the auxiliary transistors Q31 and Q32, when the auxiliary transistors Q31 and Q32 are turned on.

As noted above, an impedance including a combination of resistive and capacitive elements is electrically coupled between the base terminals of the auxiliary transistors Q31 and Q32 in the amplifier circuit 20. The resistive elements between the base terminals of the auxiliary transistors Q31 and Q32 can be implemented in other ways as compared to that shown in FIG. 4. The resistive impedance can include a single resistor, additional resistors beyond the resistors R1 and R2, resistor networks of three or more resistors, and other resistive networks. The impedance between the base terminals of the auxiliary transistors Q31 and Q32 can also include other combinations of resistive and capacitive elements, including additional more capacitors in some cases. The impedance can also include other impedance networks of resistors, capacitors, and inductors in some cases.

FIG. 4 illustrates an example plot of normalized gain for different gain settings of the amplifier circuit 20 shown in FIG. 4. Gain curves for maximum, minimum, and other gain settings are shown, over operating frequency for the amplifier circuit 20, and the maximum and minimum gain curves are separately referenced in FIG. 4. Due at least in part to use of the resistors R1 and R2, the difference in gain among the gain settings of the amplifier circuit 20 is less pronounced at the higher, peaking frequencies for the amplifier circuit 20 shown in FIG. 4 than for the amplifier circuit 10 shown in FIG. 2. At the higher, peaking frequencies of the amplifier circuit 20, the gain curves of the amplifier circuit 20 closely track each other, with one exception for the maximum gain setting, where the auxiliary transistors Q31 and Q32 present a very high “off” impedance and the gain curve has a larger peak compared to the other gain settings.

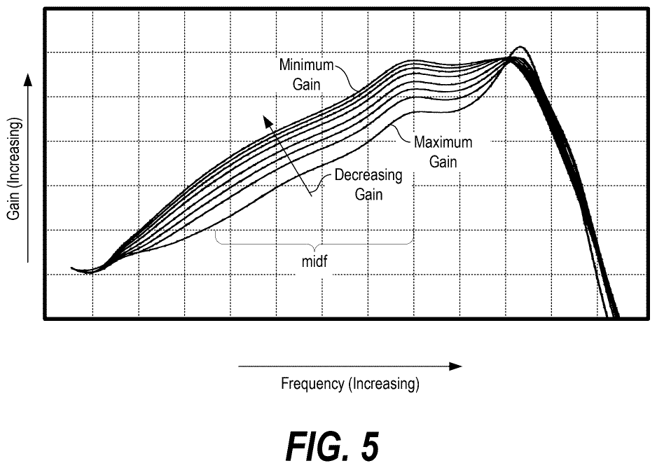

At the lower, “midf” frequencies, the gain curves for the amplifier 20 shown in FIG. 5 are spread or separated apart to a larger extent than the gain curves for the amplifier 10 shown in FIG. 3 were. For certain data communication and other applications, such as for optical communications, it can be preferrable to have less variation among the gain settings of an amplifier at higher, peaking frequencies, and more variation among the gain settings of the amplifier at lower frequencies. In that sense, the amplifier circuit 20, including the resistors R1 and R2, can present a preferred gain response as compared to the amplifier circuit 10 at both the midband and peaking frequencies. The amplifier circuit 20 also offers additional options for further control of gain at the midband frequencies.

The transistors described herein, including the transistors Q11, Q12, Q21, Q22, Q31, and Q32, can be implemented as a range of different types of transistors formed in a range of different semiconductor materials. The transistors can be formed as bipolar junction transistors, FETs, variants thereof, and other types of transistors, and the concepts can be applied to a range of transistor types. Among other types of FET transistors, the transistors described herein can be formed as high-electron mobility transistors (HEMTs), pseudomorphic high-electron mobility transistors (pHEMTs), metamorphic high-electron mobility transistors (mHEMTs), and other types of transistors. The FETs can include metal oxide or insulator semiconductor (MOSFET or MISFET) transistors and metal-semiconductor field-effect transistor (MESFETs). The transistors can include one or more field plates, such as source-connected field plates, gate-connected field plates, or both source-connected and gate-connected field plates. The transistors can be implemented in silicon germanium (SiGe), gallium arsenide (GaAs), gallium nitride (GaN), GaN materials, and other semiconductor materials on or over a range of different substrates. As non-limiting examples, the transistors can be structured as enhancement or depletion mode FET transistors, such as a depletion mode GaAs pHEMT transistors, as GaN HEMT transistors, as GaN materials HEMT transistors, or as related power transistors.

The transistors and other active devices described herein can be formed using group III-V semiconductor materials and semiconductor manufacturing processes. The group III elemental materials include scandium (Sc), aluminum (Al), gallium (Ga), and indium (In), and the group V elemental materials include nitrogen (N), phosphorus (P), arsenic (As), and antimony (Sb)). Thus, in some examples, the concepts can be applied to group III-V active semiconductor devices, such as the III-Nitrides (aluminum (Al)-, gallium (Ga)-, indium (In)-, and alloys (AlGaIn)-based Nitrides), GaAs, InP, InGaP, AlGaAs, etc. devices. However, the concepts may be applied to transistors and other active devices formed from other semiconductor materials.

The concepts described herein can be embodied by GaN-on-Si transistors and devices, GaN-on-SiC transistors and devices, as well as other types of semiconductor materials. As used herein, the phrase “gallium nitride material(s)” or “GaN material(s)” refers to gallium nitride and any of its alloys, such as aluminum gallium nitride (AlₓGa₍₁₋ₓ₎N), indium gallium nitride (In_{y}Ga_{(1-y)}N), aluminum indium gallium nitride (AlₓIn_{y}Ga_{(1-x-y)}N), gallium arsenide phosphide nitride (GaAsₐP_{b}N_{(1-a-b)}), aluminum indium gallium arsenide phosphide nitride (AlₓIn_{y}Ga_{(1-x-y)} AsₐP_{b}N_{(1-a-b)}), among others. Typically, when present, arsenic and/or phosphorous are at low concentrations (e.g., less than 5 weight percent). The gallium nitride materials can be n-type doped, p-type doped, or unintentionally doped (UID).

In embodiments with high concentrations of gallium, gallium nitride material has a high concentration of gallium and includes little or no aluminum or indium. In high gallium concentration embodiments, the sum of (x+y) may be less than 0.4 in some cases, less than 0.2 in some cases, less than 0.1 in some cases, or even less in other cases. The term “gallium nitride” or “GaN” refers directly to gallium nitride, exclusive of its alloys (i.e., x=y=a=b=0). The GaN can be n-type doped, p-type doped, or unintentionally doped (UID).

In view of the limitations of the semiconductor manufacturing and processing techniques available in the field, the terms “approximately” and “about” reflect a certain inability (or uncertainty) to precisely control the exact dimensions of certain features described herein. Depending on the level of precision that can be achieved using the commercially available semiconductor processing tools available at the time, the terms “approximately” and “about” may be used to mean within ±20% of a target value for some features, within ±10% of a target value for some features, within ±5% of a target value for some features, and within ±2% of a target value for some features. The terms “approximately” and “about” may include the target value.

The concepts described herein can be combined in one or more embodiments in any suitable manner, and the features discussed in the embodiments are interchangeable in some cases. Example embodiments are described herein, although a person of skill in the art will appreciate that the technical solutions and concepts can be practiced in some cases without all of the specific details of each example. Additionally, substitute or equivalent steps, components, materials, and the like may be employed. It should also be appreciated that some well-known process steps, semiconductor material layers, semiconductor device features, and other features have been omitted to avoid obscuring the concepts.

Although relative terms such as “on,” “below,” “upper,” “lower,” “top,” “bottom,” “right,” and “left” may be used to describe the relative spatial relationships of certain structural features, these terms are used for convenience only, as a direction in the examples. Thus, if a structure is turned upside down, the “upper” component will become a “lower” component. When a structure or feature is described as being “on” (or formed on) another structure or feature, the structure can be positioned directly on (i.e., contacting) the other structure, without any other structures or features intervening between the structure and the other structure. When a structure or feature is described as being “over” (or formed over) another structure or feature, the structure can be positioned over the other structure, with or without other structures or features intervening between them. When two components are described as being “coupled to” each other, the components can be electrically coupled to each other, with or without other components being electrically coupled and intervening between them. When two components are described as being “directly coupled to” each other, the components can be electrically coupled to each other, without other components being electrically coupled between them.

Terms such as “a,” “an,” “the,” and “said” are used to indicate the presence of one or more elements and components. The terms “comprise,” “include,” “have,” “contain,” and their variants are used to be open ended and may include or encompass additional elements, components, etc., in addition to the listed elements, components, etc., unless otherwise specified. The terms “first,” “second,” etc. may be used as differentiating identifiers of individual or respective components among a group thereof, rather than as a descriptor of a number of the components, unless clearly indicated otherwise.

Although embodiments have been described herein in detail, the descriptions are by way of example. The features of the embodiments described herein are representative and, in alternative embodiments, certain features and elements can be added or omitted. Additionally, modifications to aspects of the embodiments described herein can be made by those skilled in the art without departing from the spirit and scope of the present invention defined in the following claims, the scope of which are to be accorded the broadest interpretation so as to encompass modifications and equivalent structures.

1. An amplifier circuit with gain control comprising:
a differential transistor pair;
a main transistor pair coupled to the differential transistor pair;
an auxiliary transistor pair coupled to the differential transistor pair; and
a resistive impedance coupled between base terminals of the auxiliary transistor pair.

2. The amplifier circuit according to claim 1, wherein the resistive impedance comprises a pair of matched resistors coupled between base terminals of the auxiliary transistor pair.

3. The amplifier circuit according to claim 2, further comprising a virtual ground node between the pair of matched resistors.

4. The amplifier circuit according to claim 3, further comprising a capacitor coupled from the virtual ground node between the pair of matched resistors to ground.

5. The amplifier circuit according to claim 1, wherein:
the differential transistor pair comprises a first differential transistor and a second differential transistor;
the main transistor pair comprises a first main transistor and a second main transistor;
an emitter terminal of the first main transistor is coupled to a collector terminal of the first differential transistor; and
an emitter terminal of the second main transistor is coupled to a collector terminal of the second differential transistor.

6. The amplifier circuit according to claim 1, wherein:
the auxiliary transistor pair comprises a base-coupled auxiliary transistor pair;
the resistive impedance is coupled between base terminals of the auxiliary transistor pair; and
emitter terminals of the auxiliary transistor pair are coupled to collector terminals of the differential transistor pair.

7. The amplifier circuit according to claim 6, wherein emitter terminals of the main transistor pair are also coupled to the collector terminals of the differential transistor pair.

8. The amplifier circuit according to claim 1, wherein:
the amplifier circuit is a variable gain amplifier stage of a multi-stage amplifier; and
an input of the amplifier circuit is coupled to an output of a distributed amplifier stage of the multi-stage amplifier.

9. The amplifier circuit according to claim 1, wherein:
a differential input to the amplifier circuit is applied across base terminals of the differential transistor pair;
a differential output from the amplifier circuit is taken across collector terminals of the main transistor pair; and
a gain control signal is applied at base terminals of the main transistor pair and at the base terminals of the auxiliary transistor pair.

10. An amplifier circuit with gain control comprising:
a main transistor pair;
an auxiliary transistor pair; and
a resistive impedance coupled between base terminals of the auxiliary transistor pair.

11. The amplifier circuit according to claim 10, wherein the resistive impedance comprises a pair of matched resistors coupled between base terminals of the auxiliary transistor pair.

12. The amplifier circuit according to claim 11, further comprising a virtual ground node between the pair of matched resistors.

13. The amplifier circuit according to claim 12, further comprising a capacitor coupled from the virtual ground node between the pair of matched resistors to ground.

14. The amplifier circuit according to claim 10, wherein:
the auxiliary transistor pair comprises a base-coupled auxiliary transistor pair;
the resistive impedance is coupled between base terminals of the auxiliary transistor pair; and
emitter terminals of the auxiliary transistor pair are coupled to collector terminals of a differential transistor pair.

15. The amplifier circuit according to claim 14, wherein emitter terminals of the main transistor pair are also coupled to the collector terminals of the differential transistor pair.

16. The amplifier circuit according to claim 10, wherein:
the amplifier circuit is a variable gain amplifier stage of a multi-stage amplifier; and
an input of the amplifier circuit is coupled to an output of a distributed amplifier stage of the multi-stage amplifier.

17. An amplifier circuit comprising:
a main transistor pair;
an auxiliary transistor pair; and
an impedance including resistive and capacitive elements coupled between base terminals of the auxiliary transistor pair.

18. The amplifier circuit according to claim 17, wherein the impedance comprises a pair of matched resistors coupled between base terminals of the auxiliary transistor pair.

19. The amplifier circuit according to claim 18, further comprising a capacitor coupled from between the pair of matched resistors to ground.

20. The amplifier circuit according to claim 17, wherein:
emitter terminals of the auxiliary transistor pair are coupled to collector terminals of a differential transistor pair; and
emitter terminals of the main transistor pair are also coupled to the collector terminals of the differential transistor pair.
